(19) United States
(12) Patent Application Publication
(10) Pub. No.: US 2008/0057706 A1
(43) Pub. Date: Mar. 6, 2008

(54) METHOD FOR FORMING CYCLINDER TYPE STORAGE NODE FOR PREVENTING CREATION OF WATERMARKS

(76) Inventors: Gyu Hyun KIM, Kyoungki-do (KR); Yong Soo CHOI, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/755,112

(22) Filed: May 30, 2007

(30) Foreign Application Priority Data
Aug. 30, 2006 (KR) 10-2006-0083156

(51) Int. Cl. H01L 21/44

(52) U.S. Cl. 438/670; 257/E21.495

(57) ABSTRACT

A cylinder type storage node is made by, inter alia: forming a sacrificial oxide layer containing organic material over a semiconductor substrate; defining holes for storage nodes by etching the sacrificial oxide layer; forming storage nodes on surfaces of the holes; and removing the sacrificial oxide layer through wet etching and removing the organic material contained in the sacrificial oxide layer using ozone gas.

### CROSS-REFERENCE TO RELATED APPLICATIONS

The present application claims priority to Korean patent application number 10-2006-0083156 filed on Aug. 30, 2006, which is incorporated herein by reference in its entirety.

### BACKGROUND OF THE INVENTION

The present invention relates to a method for forming a cylinder type storage node and, more particularly, to a rinsing method which can prevent watermarks from being produced due to a full dip-out process for removing a sacrificial oxide layer containing organic material.

As high integration of a semiconductor device proceeds, the size thereof is gradually decreased. In a memory device such as a DRAM, the width of a capacitor, which serves as a storage for storing data, is also decreased. The capacitor has a structure in which a dielectric layer is interposed between a storage node and a plate node. The capacitance of the capacitor having this structure is proportional to the surface area of the electrode and the permittivity of the dielectric layer, and is inversely proportional to the distance between the electrodes and the thickness of the dielectric layer.

Therefore, in order to obtain a capacitor having high capacitance, it is necessary to employ a dielectric layer having high permittivity, or to increase the surface area of the electrode, or to decrease the distance between electrodes. Since there exists a limitation in decreasing the thickness of the dielectric layer, the research trend for obtaining a capacitor having high capacitance has been toward either employing a dielectric layer having high permittivity or increasing the surface area of an electrode.

Typically, a storage node having a three-dimensional configuration like a concave or a cylinder is used to increase the surface area of an electrode. Since a cylinder type storage node has a greater surface area of the electrode when compared to a concave type storage node, the cylinder type storage node is more advantageous when used in a high integration device.

Hereafter, a conventional method for forming a cylinder type storage node will be described with reference to FIGS. 1A through 1C.

Referring to FIG. 1A, an interlayer dielectric 102 is formed over a semiconductor substrate 101, and storage node contact plugs 103 are formed in the interlayer dielectric 102. An etch stop layer 104 of a nitride layer is formed on the interlayer dielectric 102 and the storage node contact plugs 103 formed in the interlayer dielectric 102. A sacrificial oxide layer 105 for forming cylinder type storage nodes is formed on the etch stop layer 104. The sacrificial oxide layer 105 is generally made of a PE-TEOS layer formed by PECVD.

By etching the sacrificial oxide layer 105 and the etch stop layer 104, holes H for storage nodes are defined to expose the storage node contact plugs 103. A material layer 106 for storage nodes is deposited on the surfaces of the holes H and on the sacrificial oxide layer 105 to a predetermined thickness.

Referring to FIG. 1B, portions of the material layer 106 for storage nodes, which are formed on the sacrificial oxide layer 105, are removed to separate neighboring storage nodes from one another. Storage nodes 106a are thereby formed on the surfaces of the holes H.

Referring to FIG. 1C, the remaining sacrificial oxide layer 105 is removed through a full dip-out process using buffered oxide etch (BOE) solution, and as a result the formation of the cylinder type storage nodes 106a is completed.

However, when forming a cylinder type storage node by the conventional method as described above, watermarks are produced when conducting the full dip-out processwatermark due to organic material in the sacrificial oxide layer having the PE-TEOS layer. Cell-to-cell bridging occurs as a result of the watermarks.

In greater detail, a sacrificial oxide layer formed by a CVD process usually contains organic material by-product. The sacrificial oxide layer is removed from a semiconductor substrate when conducting the full dip-out process using BOE solution. Although the sacrificial oxide layer is completely removed from the semiconductor substrate by the full dip-out process using BOE solution, the organic material is not completely removed but partly remains. This remaining organic material is still not completely removable even during a subsequent rinsing process using deionized water.

As a result, the remaining organic material produces watermarks as shown in FIG. 2 in a drying process following the rinsing process, thereby causing cell-to-cell bridging.

FIG. 3 shows the results obtained by analyzing the constituents of the organic material, which causes the cell-to-cell bridging. The organic material is composed of silicon (Si), oxygen (O), and carbon (C), which are typical constituents of a watermark.

FIG. 4 shows a fail map in a wafer showing spots of failures resulting from the cell-to-cell bridging.

### SUMMARY OF THE INVENTION

An embodiment of the present invention is directed to a method of forming a cylinder type storage node which can prevent a watermark from being produced in a full dip-out process for a sacrificial oxide layer containing organic material.

Also, an embodiment of the present invention is directed to a method of forming a cylinder type storage node that can avoid cell-to-cell bridging by preventing a watermark from being produced.

In one embodiment, a method for forming a cylinder type storage node comprises steps of: forming a sacrificial oxide layer containing organic material over a semiconductor substrate; defining holes for storage nodes by etching the sacrificial oxide layer; forming storage nodes on surfaces of the holes; and removing the sacrificial oxide layer through wet etching and removing the organic material contained in the sacrificial oxide layer by using ozone gas.

The sacrificial oxide layer is formed by a chemical vapor deposition (CVD) process in a manner such that the organic material is contained in the sacrificial oxide layer as a by-product.

The sacrificial oxide layer is formed from one of a PE-TEOS layer, an O₃-TEOS layer, an O₃-USG layer, a PSG layer, a stack of a PSG layer and a PE-TEOS layer, and a stack of a BPSG layer and a PE-TEOS layer.

Removal of the sacrificial oxide layer and the organic material is implemented in a manner such that the semiconductor substrate which has the storage nodes formed thereon is dipped into etching solution. The semiconductor substrate from which the sacrificial oxide layer was removed is then rinsed using deionized water mixed with ozone gas in order to remove the organic material.

The removal of the sacrificial oxide layer is implemented using a buffered oxide etching (BOE) solution or a diluted hydrofluoric (HF) acid solution.

The diluted HF solution is composed of about 49% HF solution and H₂O mixed at a ratio in the range of 1:5˜1:10.

A concentration of the ozone gas in the deionized water mixed with the ozone gas is in the range of 5˜200 ppm.

The removal of the organic material is implemented for 1˜10 minutes.

After the step of removing the sacrificial oxide layer and the organic material, the method further comprises the step of drying the semiconductor substrate from which the sacrificial oxide layer and the organic material have been removed.

Drying of the semiconductor substrate is performed by either an isopropyl alcohol (IPA) gas dryer, a Marangoni dryer, or an IPA gas spin dryer.

The sacrificial oxide layer and the organic material are removed by dipping the semiconductor substrate into an etching solution mixed with ozone gas in order to simultaneously remove the sacrificial oxide layer and the organic material.

In another embodiment, a method for forming a cylinder type storage node comprises steps of: forming a sacrificial oxide layer containing organic material over a semiconductor substrate through CVD; defining holes for storage nodes by etching the sacrificial oxide layer; forming storage nodes on the surfaces of the holes; removing the sacrificial oxide layer by dipping the semiconductor substrate formed with the storage nodes in a bath filled with an etching solution; removing the organic material by rinsing the semiconductor substrate from which the sacrificial oxide layer has been removed by using deionized water mixed with ozone gas; and drying the semiconductor substrate from which the sacrificial oxide layer and the organic material have been removed.

The sacrificial oxide layer is formed from one of a PE-TEOS layer, an O₃-TEOS layer, an O₃-USG layer, a PSG layer, a stack of a PSG layer and a PE-TEOS layer, and a stack of a BPSG layer and a PE-TEOS layer.

Removal of the sacrificial oxide layer is implemented by using a BOE solution or a diluted HF solution in which about 49% HF solution and H₂O are mixed at a ratio in the range of 1:5˜1:10.

Ozone gas is mixed with deionized water to the concentration of 5˜200 ppm.

The removal of the organic material is implemented for 1˜10 minutes.

In still another embodiment, a method for forming a cylinder type storage node, comprises steps of: forming a sacrificial oxide layer containing organic material over a semiconductor substrate through CVD; defining holes for storage nodes by etching the sacrificial oxide layer; forming storage nodes on the surfaces of the holes; removing the sacrificial oxide layer and the organic material by dipping the semiconductor substrate formed with the storage nodes in a bath filled with an etching solution which is mixed with one of ozone gas, hydrogen peroxide, and peroxy-aceticacid; and drying the semiconductor substrate from which the sacrificial oxide layer and the organic material were removed.

The sacrificial oxide layer is formed from one of a PE-TEOS layer, an O₃-TEOS layer, an O₃-USG layer, a PSG layer, a stack of a PSG layer and a PE-TEOS layer, and a stack of a BPSG layer and a PE-TEOS layer.

The etching solution comprises either a BOE solution or a diluted HF solution in which 49% HF solution and H₂O are mixed in a ratio in the range of of 1:5˜1:10.

The hydrogen peroxide or peroxy-aceticacid is mixed in a ratio in the range of 1/50˜1/100 with respect to the volume of the etching solution.

### BRIEF DESCRIPTION OF THE DRAWINGS

FIGS. 1A through 1C are cross-sectional views illustrating the process steps of a conventional method for forming a cylinder type storage node.

FIG. 2 is a black and white photograph showing examples of watermarks produced and cell-to-cell bridging occurs due to the presence of watermarks in the conventional art.

FIG. 3 is a black and white photograph illustrating the analysis results for analyzing the constituents of the organic material that causes the cell-to-cell bridging and an associated table of elements listing the compositional make up of the organic material.

FIG. 4 shows a fail map showing the spots of failure on a wafer resulting from the cell-to-cell bridging.

FIGS. 5A through 5H are cross-sectional views illustrating a method of forming a cylinder type storage node in accordance with various embodiments of the present invention.

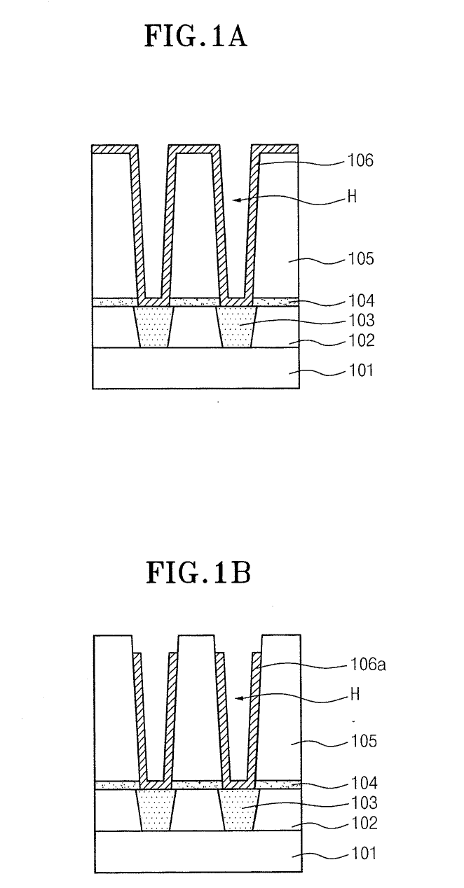

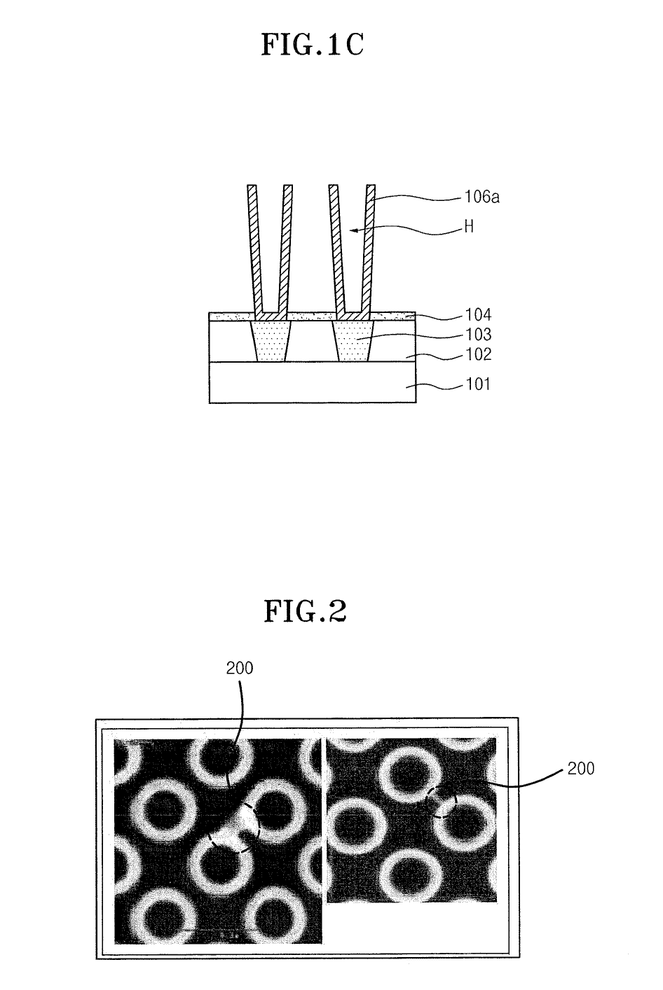

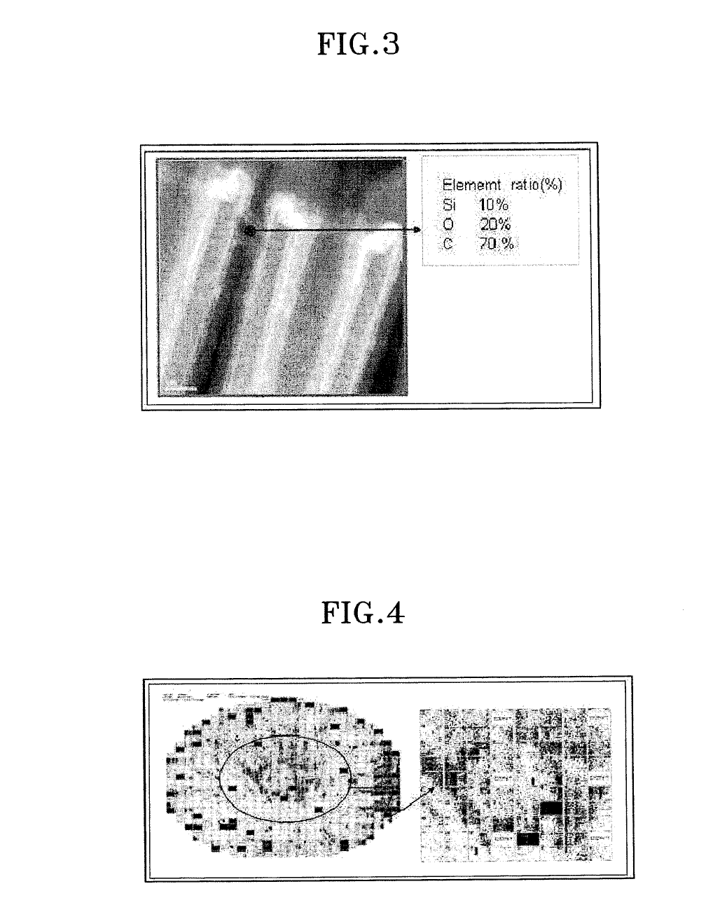

### DESCRIPTION OF SPECIFIC EMBODIMENT

In an embodiment of the present invention, after a sacrificial oxide layer containing organic material is removed through a full dip-out process, the organic material is removed through a rinsing process using deionized water containing ozone (O₃) gas. A drying process is then performed.

Since the organic material is decomposed and completely removed by the ozone gas, watermarks are prevented from being produced if any organic material were to remain. Cell-to-cell bridging and a failures due to watermarks are therefore avoided.

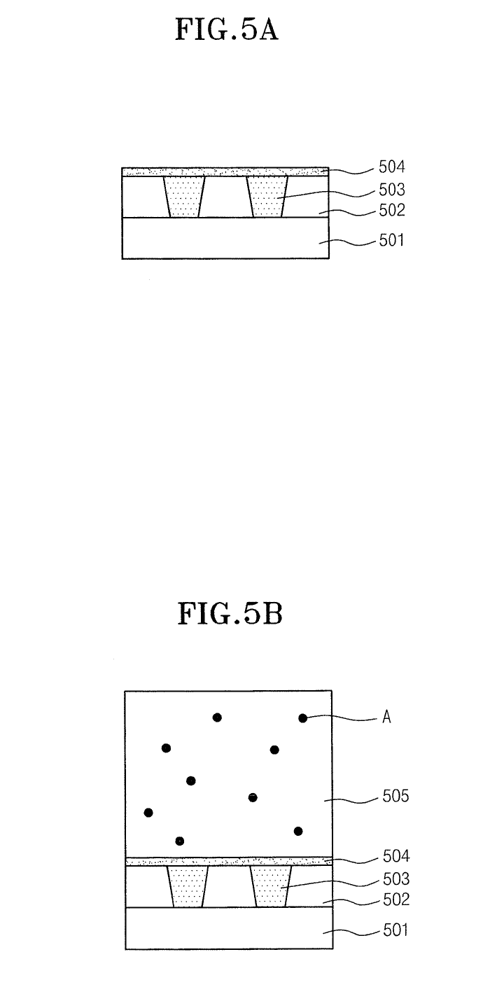

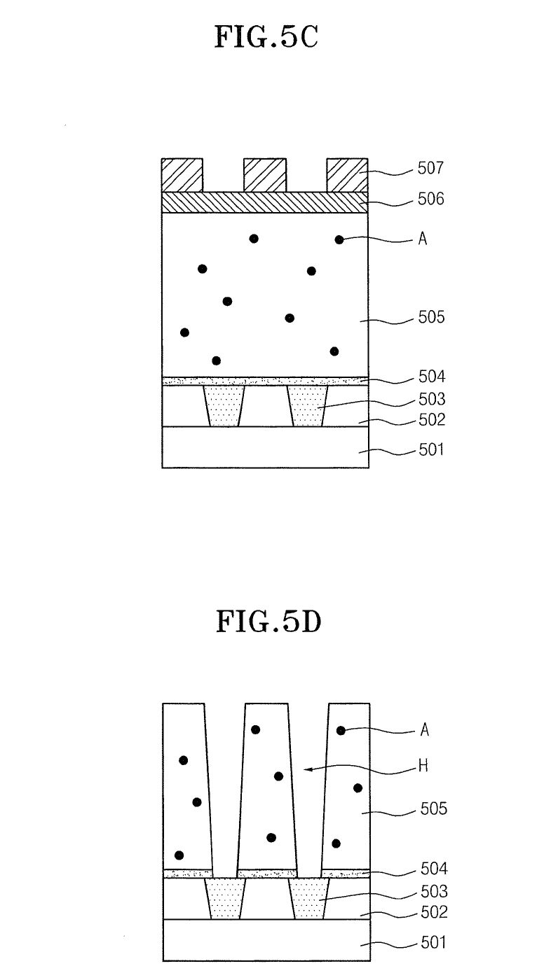

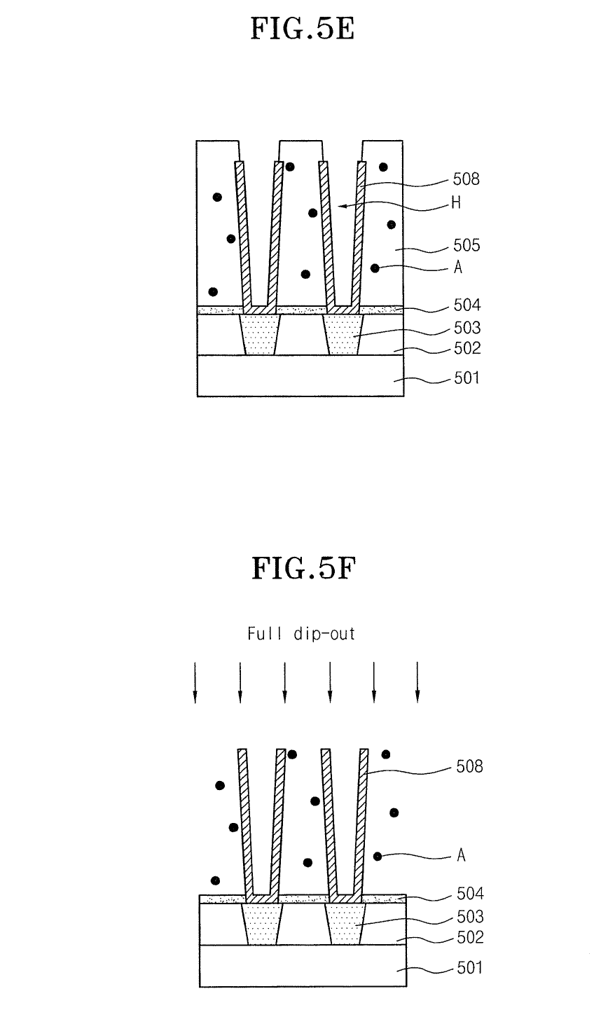

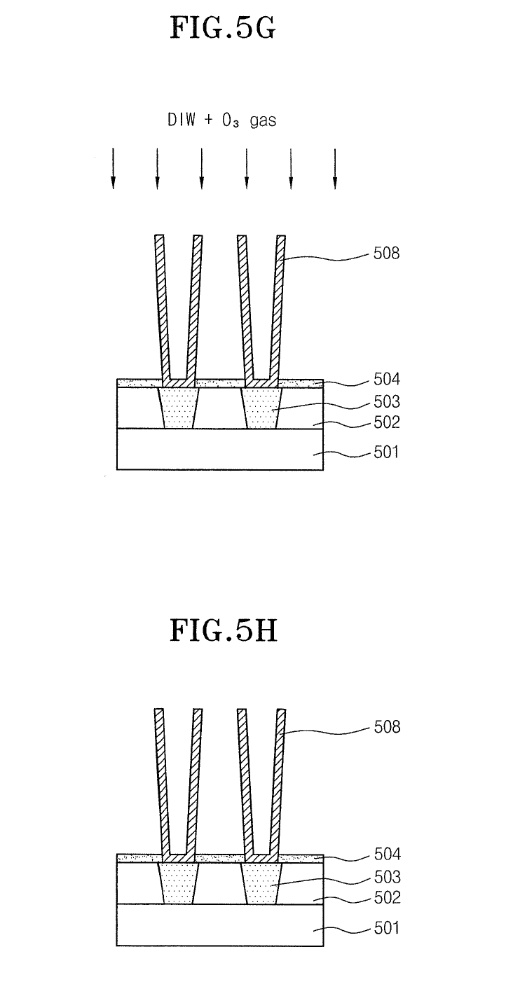

Hereafter, the processes for forming a cylinder type storage node in accordance with various embodiments of the present invention will be described in detail with reference to FIGS. 5A through 5H.

Referring to FIG. 5A, an interlayer dielectric 502 is formed over a semiconductor substrate 501 formed with predeposition layers including bit lines, and storage node contact plugs 503 are formed in the interlayer dielectric 502. An etch stop nitride layer 504 is formed on the interlayer dielectric 502 and the storage node contact plugs 503 formed in the interlayer dielectric 502.

The etch stop nitride layer 504 protects a lower structure, that is, the interlayer dielectric 502 and the storage node contact plugs 503, from being attacked in a subsequent full dip-out process for removing a sacrificial oxide layer. The etch stop nitride layer 504 is formed to a thickness in the range of 600˜1,000 Å in a furnace using N₂ gas, NH₃ gas, and dichlorosilane (DCS) gas (e.g., SiH₂Cl₂) at a temperature in the range of 700˜720° C. Preferably, the etch stop nitride layer 504 is formed at the temperature of 710° C. to the thickness of 800 Å.

Referring to FIG. 5B, a sacrificial oxide layer 505 which serves as a mold for forming cylinder type storage nodes is formed on the etch stop nitride layer 504. The sacrificial oxide layer 505 may be formed by a chemical vapor deposition (CVD) process, for example, as a plasma enhanced trtra-ethyl-ortho-silicate (PE-TEOS) layer, an O₃-TEOS layer, an ozone-updoped silicate glass (O₃-USG) layer, a phosphoro-silicate glass (PSG) layer, a stack of a PSG layer and a PE-TEOS layer, or a stack of a borophosphosilicate glass (BPSG) layer and a PE-TEOS layer, preferably, as a PE-TEOS layer.

In the sacrificial oxide layer 505 (which may be formed by CVD), the organic material ‘A’ is produced according to Formula 1 such that the sacrificial oxide layer 505 contains therein the organic material ‘A’:

TEOS (Si(OC₂H₅)₄)+O₂→SiO₂+organic material (A) [FORMULA 1]

Referring to FIG. 5C, a hard mask layer 506 and a mask pattern 507 are sequentially formed on the sacrificial oxide layer 505. The hard mask layer 506 may be formed as a polysilicon layer. The mask pattern 507 defines the areas of the storage node forming regions. The hard mask layer 506 comprising the polysilicon layer is formed to solve the problems due to possible partial collapsing of the sides of holes for storage nodes during a subsequent etching process when performed without the hard mask layer 506, since sufficient selectivity may not always be secured when only the mask pattern 507 were to be used.

Referring to FIG. 5D, portions of the hard mask layer 506 exposed by the mask pattern 507 are etched using gases including at least one or more of hydrogen bromide (HBr), chlorine (Cl₂), and oxygen (O₂). By etching the sacrificial oxide layer 505 using the unetched portions of the hard mask layer 506 as an etch mask, holes ‘H’ for storage nodes are formed in the sacrificial oxide layer 505. The sacrificial oxide layer 505 may be etched using gases including at least one or more of hexafluorobutadiene (C₄F₆), O₂, and tetrafluoromethane (CF₄).

After removing the mask pattern 507, the hard mask layer 506 is removed through etching which uses hexafluoroethane (C₂F₆) and O₂ gas. By removing the portions of the etch stop nitride layer 504, which are exposed on bottoms of the holes ‘H’ for storage nodes due to etching of the sacrificial oxide layer 505, the storage node contact plugs 503 are exposed.

Referring to FIG. 5E, a TiN layer is deposited on the surfaces of the holes ‘H’ and the sacrificial oxide layer 505 as the conductive layer for the storage nodes 508 through CVD to a thickness of about 300 Å. By selectively removing the portions of the TiN layer formed on the sacrificial oxide layer 505 through a plasma etching process using, for example, C1₂ and/or argon (Ar) as the etching gas(es), the storage nodes 508 are formed inside and on the surfaces of the holes ‘H’. The storage nodes 508 may be formed using a tungsten (W) layer, a ruthenium (Ru) layer or a polysilicon layer instead of the TiN layer.

Here, the portions of the storage node 508 (e.g., the TiN layer) formed on the bottoms of the holes ‘H’ are not removed. This is possible by the fact that, when conducting an etching process, etching conditions are adjusted to decrease directionality of etching gas so that the etching gas does not reach the bottoms of the holes ‘H’ having a very fine width. This selective etching process for the storage node 508 of, for example, the TiN layer is called isolation of the storage nodes 508.

Referring to FIG. 5F, the remaining sacrificial oxide layer 505 is removed through a full dip-out process using etching solution. The full dip-out process involves dipping the semiconductor substrate 501 having the storage nodes 508 formed thereon in an etching solution bath. As the etching solution, the buffered oxide etch (BOE) solution, in which 17% ammonium fluoride (NH₄F) solution and 1.7% hydrofluoric (HF) solution are mixed, or diluted HF solution, in which 49% HF solution and water (H₂O) are mixed at a ratio of 1:5˜1:10, is used.

As a result of the full dip-out process, while the sacrificial oxide layer is completely removed, the organic material ‘A’ contained in the sacrificial oxide layer is not removed but remains.

Referring to FIG. 5G, the semiconductor substrate 501 having the storage nodes 508 with the sacrificial oxide layer 505 removed is dipped and rinsed in a bath filled with deionized water. By introducing ozone (O₃) gas through bottom of the bath filled with deionized water, ozonized water is produced. By rinsing the semiconductor substrate 501 having the storage nodes 508 with the sacrificial oxide layer 505 removed in the ozonized water, the organic material is decomposed and completely removed as expressed in the following FORMULAS 2 and 3.

O₃→O*+O₂ [FORMULA 2]

20*+organic material (—CH₂—)→CO₂+H₂ [FORMULA 3]

Here, * designates radicals. Radicals represent a group of atoms which are not decomposed when a chemical reaction occurs and move to the other molecules.

The concentration of the deionized water containing ozone gas (that is, the ozone gas contained in the ozonized water) or the execution time of the rinsing process is not particularly limited a predefined range. However, it is preferred that the concentration of the ozone gas be in the range of 5˜200 ppm, and the execution time of the rinsing process be anywhere in the range of 1˜10 minutes.

According to an embodiment of the present invention, since the semiconductor substrate 501 with the sacrificial oxide layer 505 removed is rinsed using deionized water mixed with ozone gas, the organic material by-product produced when forming the sacrificial oxide layer 505 is decomposed and completely removed. Therefore, it is possible to prevent watermarks from being created by any organic material undesirably remaining. Also, according to an embodiment of the present invention, by partially oxidating the storage node 508 such as but not limited to the TiN layer through the rinsing process using the ozonized water, a contact angle between the storage node 508 and the deionized water can be decreased to make the storage node 508 hydrophobic. This leads to an improved subsequent drying process, which then helps to further suppress any creation of watermarks.

Therefore, as the watermarks are prevented from forming, the cell-to-cell bridging and failures present in a wafer caused due to the watermarks are prevented.

FIG. 5H shows the semiconductor substrate 501 having the storage nodes 508, among others, that is rinsed is dried completely. The drying of the semiconductor substrate 501 is performed using an isopropyl alcohol (IPA) gas dryer, a Marangoni dryer, or an IPA gas spin dryer.

In an embodiment of the present invention, rinsing is conducted using deionized water containing ozone gas to remove organic material after finishing the wet etching process to remove the sacrificial oxide layer 505. However, in another embodiment of the present invention, both the sacrificial oxide layer and the organic material can be removed simultaneously by introducing ozone gas into the etching solution used for removing the sacrificial oxide layer.

As already described above, the ozone gas may be introduced into the etching solution in order to remove the organic material. Alternatively, however, hydrogen peroxide (H₂O₂) or peroxy-aceticacid (CH₃COOOH) may be mixed instead of ozone gas. It is preferred that the hydrogen peroxide or peroxy-aceticacid be mixed at a ratio in the range of 1/50˜1/100 with respect to the volume of the etching solution.

As is apparent from the above description, the watermarks are prevented from forming according to an embodiment of the present invention, since the organic material produced when forming a sacrificial oxide layer is decomposed and removed by using ozone gas. Consequently, the cell-to-cell bridging and failures in a wafer due to presence of watermarks are prevented.

Although a specific embodiment of the present invention has been described for illustrative purposes, those skilled in the art will appreciate that various modifications, additions and substitutions are possible, without departing from the scope and the spirit of the invention as disclosed in the accompanying claims.

What is claimed is:

1. A method for forming a cylinder type storage node comprising the steps of:
forming a sacrificial oxide layer containing organic material over a semiconductor substrate;
defining holes for storage nodes by etching the sacrificial oxide layer;
forming storage nodes on surfaces of the holes; and
removing the sacrificial oxide layer through wet etching and removing the organic material contained in the sacrificial oxide layer using ozone gas.

2. The method according to claim 1, wherein the sacrificial oxide layer is formed by CVD in a manner such that the organic material by-product is contained in the sacrificial oxide layer.

3. The method according to claim 2, wherein the sacrificial oxide layer is formed as one of a PE-TEOS layer, an O₃-TEOS layer, an O₃-USG layer, a PSG layer, a stack of a PSG layer and a PE-TEOS layer, and a stack of a BPSG layer and a PE-TEOS layer.

4. The method according to claim 1, wherein the sacrificial oxide layer and the organic material are removed by dipping the semiconductor substrate having the storage nodes formed thereon into etching solution to remove the sacrificial oxide layer, and then rinsing the semiconductor substrate from which the sacrificial oxide layer is removed using deionized water mixed with ozone gas to remove the organic material.

5. The method according to claim 4, wherein the sacrificial oxide layer is removed by using a BOE solution or a diluted HF solution.

6. The method according to claim 5, wherein the diluted HF solution comprises exactly or about 49% HF solution and H₂O which are mixed at a ratio in the range of 1:5˜1:10.

7. The method according to claim 4, wherein a concentration of the ozone gas in the deionized water mixed with the ozone gas is 5˜200 ppm.

8. The method according to claim 4, wherein the removal of the organic material is implemented for 1˜10 minutes.

9. The method according to claim 1 further comprising the step of:
drying the semiconductor substrate after removing the sacrificial oxide layer and the organic material.

10. The method according to claim 9, wherein drying of the semiconductor substrate is performed using one of an IPA gas dryer, a Marangoni dryer, and an IPA gas spin dryer.

11. The method according to claim 1, wherein the step of removing the sacrificial oxide layer and the organic material is implemented by dipping the semiconductor substrate into etching solution mixed with ozone gas to simultaneously remove the sacrificial oxide layer and the organic material.

12. The method according to claim 11, wherein removal of the sacrificial oxide layer is implemented using a BOE solution or a diluted HF solution comprising about 49% HF solution and H₂O mixed at a ratio in the range of 1:5˜1:10.

13. The method according to claim 12 further comprising the step of:
drying the semiconductor substrate after removing the sacrificial oxide layer and the organic material.

14. A method for forming a cylinder type storage node comprising the steps of:
forming a sacrificial oxide layer containing organic material over a semiconductor substrate through CVD;
defining holes for storage nodes by etching the sacrificial oxide layer;
forming storage nodes on the surfaces of the holes;
removing the sacrificial oxide layer by dipping the semiconductor substrate formed with the storage nodes in a bath filled with etching solution;
removing the organic material by rinsing the semiconductor substrate removed with the sacrificial oxide layer using deionized water mixed with ozone gas; and
drying the semiconductor substrate from which the sacrificial oxide layer and the organic material are removed.

15. The method according to claim 14, wherein the sacrificial oxide layer is formed as one of a PE-TEOS layer, an O₃-TEOS layer, an O₃-USG layer, a PSG layer, a stack of a PSG layer and a PE-TEOS layer, and a stack of a BPSG layer and a PE-TEOS layer.

16. The method according to claim 14, wherein removal of the sacrificial oxide layer is implemented using a BOE solution or a diluted HF solution comprising about 49% HF solution and H₂O mixed at a ratio in the range of 1:5˜1:10.

17. The method according to claim 14, wherein a concentration of the ozone gas in the deionized water mixed with the ozone gas is 5˜200 ppm.

18. The method according to claim 14, wherein the removal of the organic material is implemented for 1˜10 minutes.

19. A method for forming a cylinder type storage node comprising the steps of:
forming a sacrificial oxide layer containing organic material over a semiconductor substrate through CVD;
defining holes for storage nodes by etching the sacrificial oxide layer;
forming storage nodes on surfaces of the holes;
removing the sacrificial oxide layer and the organic material by dipping the semiconductor substrate formed with the storage nodes in a bath filled with etching solution which is mixed with one of ozone gas, hydrogen peroxide, and peroxy-aceticacid; and
drying the semiconductor substrate from which the sacrificial oxide layer and the organic material are removed.

20. The method according to claim 19, wherein the sacrificial oxide layer is formed as one of a PE-TEOS layer, an O₃-TEOS layer, an O₃-USG layer, a PSG layer, a stack of a PSG layer and a PE-TEOS layer, and a stack of a BPSG layer and a PE-TEOS layer.

21. The method according to claim 19, wherein the etching solution comprises a BOE solution or a diluted HF solution comprising about 49% HF solution and H₂O mixed at a ratio in the range of 1:5˜1:10.

22. The method according to claim 19, wherein the hydrogen peroxide or peroxy-aceticacid is mixed at a ratio in the range of 1/50˜1/100 with respect to the volume of the etching solution.
